(19) United States
(12) Patent Application Publication
(10) Pub. No.: US 2026/0068181 A1
(43) Pub. Date: Mar. 5, 2026

(54) THREE-DIMENSIONAL DYNAMIC RANDOM-ACCESS MEMORY (3D DRAM) STRUCTURE WITH VERTICAL SEPARATION OF A MEMORY CELL ARRAY

(71) Applicant: QUALCOMM Incorporated, San Diego, CA (US)

(72) Inventors: Jihong CHOI, San Diego, CA (US); Mustafa BADAROGLU, San Diego, CA (US); Woo Tag KANG, San Diego, CA (US); Giridhar NALLAPATI, San Diego, CA (US); Zhongze WANG, San Diego, CA (US); Periannan CHIDAMBARAM, San Diego, CA (US)

(21) Appl. No.: 19/219,871

(22) Filed: May 27, 2025

Related U.S. Application Data
(60) Provisional application No. 63/688,857, filed on Aug. 29, 2024.

(51) Int. Cl. H10B 80/00; H01L 23/00; H01L 25/00; H01L 25/065; H01L 25/18

(52) U.S. Cl. CPC H10B 80/00

(57) ABSTRACT

A three-dimensional (3D) memory structure is described. The 3D memory structure includes a first memory die having a memory cell array coupled to a wordline-bitline fanout structure. Additionally, the 3D memory structure includes a second memory die having peripheral logic formed from a second semiconductor substrate. A backside of the second memory die is hybrid bonded with a backside of the first memory die.

### CROSS-REFERENCE TO RELATED APPLICATION

The present application claims the benefit of U.S. Provisional Patent Application No. 63/688,857, filed Aug. 29, 2024, and titled “THREE-DIMENSIONAL DYNAMIC RANDOM-ACCESS MEMORY (3D DRAM) STRUCTURE WITH VERTICAL SEPARATION OF A MEMORY CELL ARRAY,” the disclosure of which is expressly incorporated by reference herein in its entirety.

### BACKGROUND

### Field

Aspects of the present disclosure relate to integrated circuits (ICs) and, more particularly, to a three-dimensional dynamic random-access memory (3D DRAM) structure with vertical separation of a memory cell array.

### Background

Memory is a vital component for computing devices, wireless communications devices, and other like computing devices. For example, a cell phone may integrate memory as part of an application processor, such as a system-on-chip (SoC) including a central processing unit (CPU), neural processing unit (NPU), and a graphics processing unit (GPU). Successful operation of some wireless applications depends on the availability of high-capacity and low-latency memory solutions for scalability of processor workload. A semiconductor memory device solution for providing a high-capacity, low-latency, and high-bandwidth memory is an existing goal for system designers.

Semiconductor memory devices include, for example, a dynamic random-access memory (DRAM). A DRAM cell includes one transistor and one capacitor, thereby providing a high degree of integration. In practice, memory intensive applications (e.g., artificial intelligence (AI)) consume extensive amounts of DRAM. A high-bandwidth, high-capacity DRAM stack is important for enabling AI. High-bandwidth DRAM stacking involves a separate logic base die stack. Unfortunately, DRAM die area scaling for implementing high-bandwidth DRAM is stagnating. Therefore, a solution for implementing a high-bandwidth, high-capacity DRAM\ stack is desired.

### SUMMARY

A three-dimensional (3D) memory structure is described. The 3D memory structure includes a first memory die having a memory cell array coupled to a wordline-bitline fanout structure. Additionally, the 3D memory structure includes a second memory die having peripheral logic formed from a second semiconductor substrate. A backside of the second memory die is hybrid bonded with a backside of the first memory die.

A high-bandwidth memory (HBM)-processor-in-memory (PIM) structure is described. The HBM-PIM structure includes a multilayer stack of three-dimensional (3D) memory structures. Each of the 3D memory structures includes a first memory die having a memory cell array coupled to a wordline-bitline fanout structure. Additionally, each of the 3D memory structures includes a second memory die having peripheral logic formed from a second semiconductor substrate. A backside of the second memory die is hybrid bonded with a backside of the first memory die.

A method for fabricating a three-dimensional (3D) memory structure is described. The method includes forming a first memory die having a memory cell array coupled to a wordline-bitline fanout structure. The method also includes forming a second memory die having peripheral logic formed from a second semiconductor substrate. The method further includes hybrid bonding a backside of the second memory die with a backside of the first memory die according to a hybrid bonding process (HBP).

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), including a three-dimensional (3D) memory structure having vertical separation of the memory cell array, in accordance with certain aspects of the present disclosure.

FIG. 2 shows a cross-sectional view of a stacked integrated circuit (IC) package of a three-dimensional (3D) memory structure having vertical separation of the memory cell array of the host system-on-chip (SoC) of FIG. 1.

FIG. 3 is a block diagram illustrating a three-dimensional (3D) high-bandwidth memory (HBM) dynamic random-access memory (DRAM) stack having a memory cell array.

FIGS. 4A and 4B are block diagrams illustrating a three-dimensional (3D) memory structure having vertical separation of a memory cell array, according to various aspects of the present disclosure.

FIGS. 5A-5F are cross-sectional diagrams illustrating a process for fabricating the three-dimensional (3D) memory structure of FIG. 4A, having vertical separation of a memory cell array, according to various aspects of the present disclosure.

FIG. 6 illustrates a high-bandwidth memory (HBM)-processor-in-memory (PIM) structure having a four-memory die height (4H) including four levels, according to various aspects of the present disclosure.

FIG. 7 is a process flow diagram illustrating a method for fabricating a three-dimensional (3D) memory structure having vertical separation of a memory cell array, according to various aspects of the present disclosure.

FIG. 8 is a block diagram showing an exemplary wireless communications system, in which an aspect of the present disclosure may be advantageously employed.

FIG. 9 is a block diagram illustrating a design workstation used for circuit, layout, and logic design of a semiconductor component such as the three-dimensional (3D) stacked chip disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workload. A semiconductor memory device solution for providing a high-capacity, low-latency, and high-bandwidth memory is an existing goal for system designers.

Semiconductor memory devices include, for example, dynamic random-access memory (DRAM). A DRAM cell includes one transistor and one capacitor, thereby providing a high degree of integration. In practice, memory intensive applications (e.g., artificial intelligence (AI)) require extensive amounts of DRAM. A high-bandwidth, high-capacity DRAM stack is an important solution for enabling AI. High-bandwidth DRAM stacking involves a separate logic base die stack. Unfortunately, DRAM die area scaling for implementing high-bandwidth DRAM is stagnating. Therefore, a solution for implementing a high-bandwidth, high-capacity DRAM stack is desired.

Various aspects of the present disclosure are directed to forming a three-dimensional dynamic random-access memory (3D DRAM) structure having vertical separation of the memory cell array. The process flow for fabrication of a high-bandwidth, high-capacity memory stack includes hybrid bonding of a DRAM die and a logic process technology die. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably.

Various aspects of the present disclosure are directed to a 3D stack DRAM structure with peripheral logic in a separate layer utilizing tight pitch nano-through silicon via (TSV) connections. In various aspects of the present disclosure, a 3D DRAM structure having vertical separation of the memory cell array significantly improves DRAM cell capacity in a given X-Y form factor. Additional processor-in-memory (PIM) logic is supported without a die X-Y form factor size increase. For example, the PIM logic integrates processing capabilities directly into the 3D stack DRAM structure, enabling data operations in or near the 3D stack DRAM structure. This integration enables computations in or near the 3D stack DRAM structure, which beneficially reducing data movement and potential processor/memory bottlenecks. This high-bandwidth multi-layer 3D DRAM stacking avoids the use of a base logic die. Additionally, a complete separation of the DRAM and logic process technology enables easy adoption of advanced logic processes, while DRAM cell process technology can evolve without co-integration process challenges for the peripheral logic.

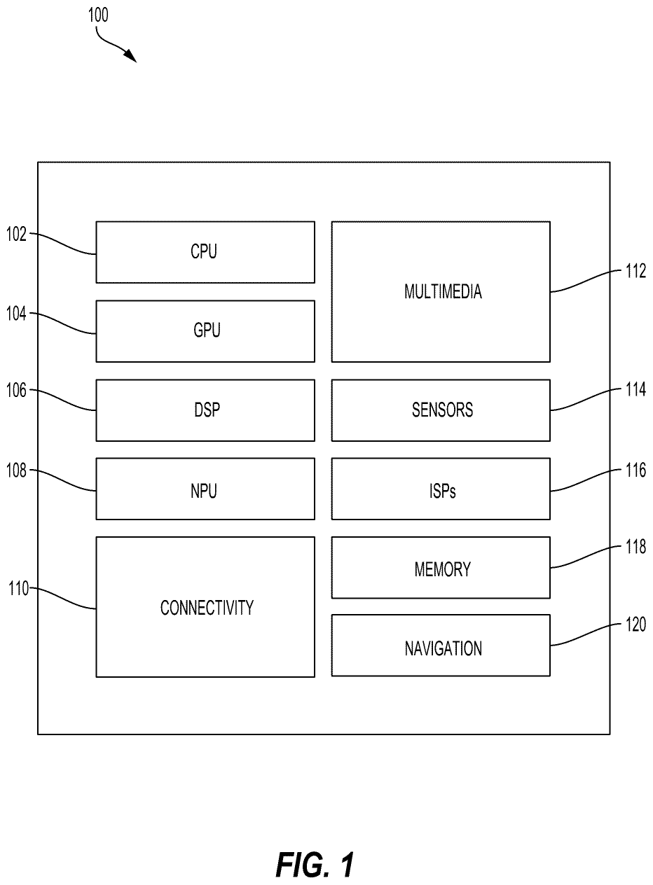

FIG. 1 illustrates an example implementation of a host system-on-chip (SoC) 100, which includes a three-dimensional (3D) memory structure having vertical separation of the memory cell array, in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

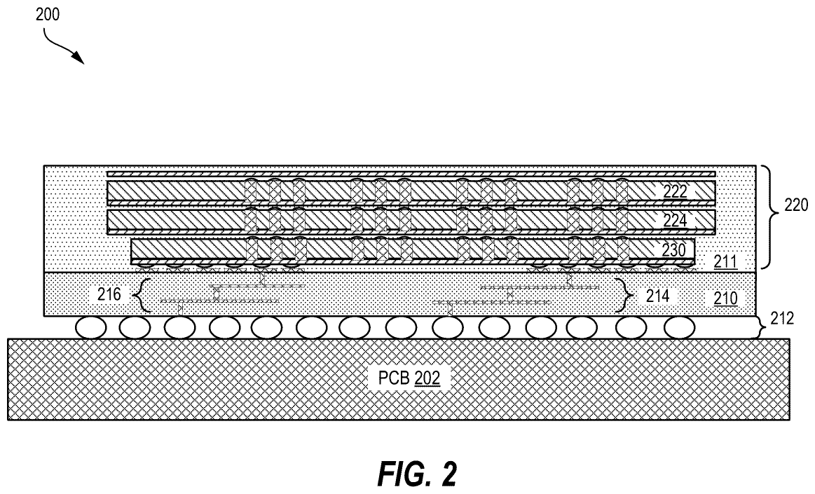

FIG. 2 shows a cross-sectional view of a stacked integrated circuit (IC) package 200 of a three-dimensional (3D) memory structure having vertical separation of the memory cell array of the host system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the three-dimensional (3D) memory structure having vertical separation of the memory cell array of the host SoC 100 of FIG. 1.

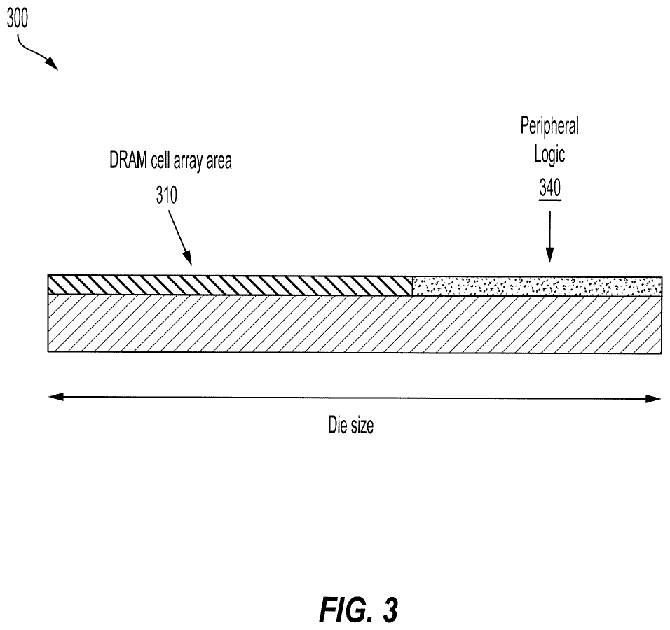

FIG. 3 is a block diagram illustrating a three-dimensional (3D) high-bandwidth memory (HBM) dynamic random-access memory (DRAM) stack 300. In this example, the 3D HBM DRAM stack 300 includes a DRAM cell array 310 and a peripheral logic area 340 in a same layer. In practice, memory intensive applications (e.g., artificial intelligence (AI)) require extensive amounts of DRAM. The high-bandwidth, high-capacity 3D HBM DRAM stack 300 is an important solution for enabling AI. Unfortunately, DRAM die area scaling for implementing high-bandwidth DRAM including processor-in-memory (PIM) functionality is stagnating with the DRAM cell array 310 and a peripheral logic area 340 in the same layer.

In practice, a PIM architecture supplies computation and processing capability near memory instead of transferring significant amounts of data to/from a computing unit. PIM architectures may operate at the cell level of a data array, at the sense amplifier/row-buffer level, and/or near memory banks that can execute a subset of CPU instructions. Additionally, PIM architectures may be designed for specific applications, including AI applications, such as deep neural network (DNN) applications, or other like AI functions. Such implementations of PIM architectures, however, are stagnating with the DRAM cell array 310 and a peripheral logic area 340 in the same layer, as shown in FIG. 3. Therefore, a solution for implementing a high-bandwidth, high-capacity DRAM stack including PIM functionality is desired.

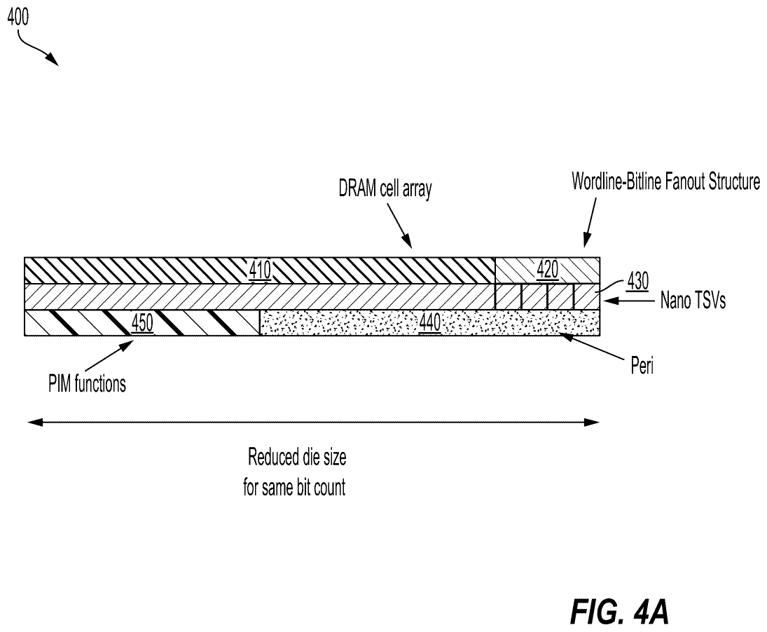

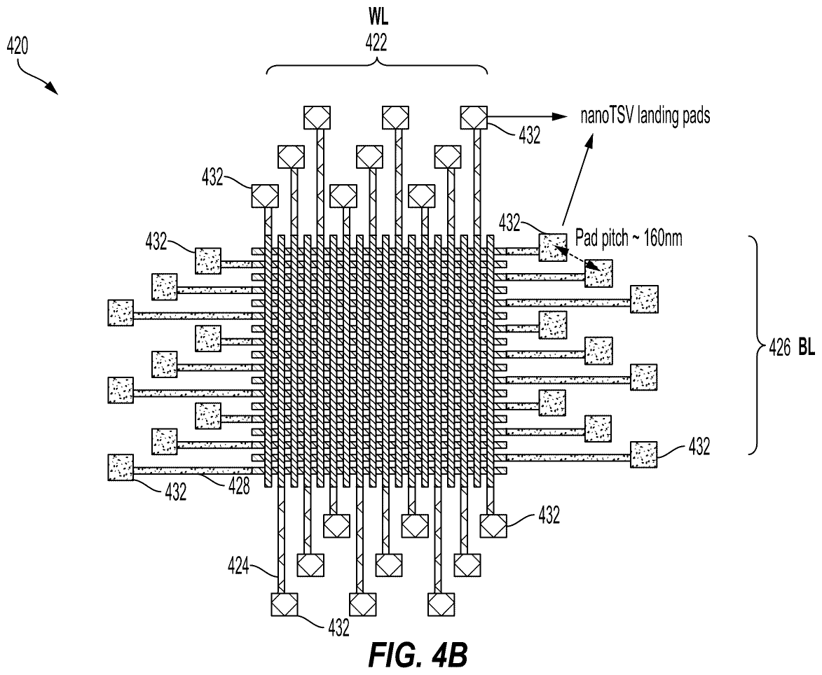

In various aspects of the present disclosure, a 3D memory structure having vertical separation of a memory cell array is integrated in the stacked IC package 200 with peripheral logic and PIM functionality in a separate layer from the memory cell array utilizing tight pitch nano-through silicon via (TSV) connections, for example, as shown in FIGS. 4A to 6.

FIGS. 4A and 4B are block diagrams illustrating a three-dimensional (3D) memory structure 400 having vertical separation of a memory cell array, according to various aspects of the present disclosure. As shown in FIG. 4A, the 3D memory structure 400 is implemented with a vertical separation between a memory cell array layer and a peripheral logic as well as processor-in-memory (PIM) logic 450 in a separate layer. The PIM logic 450 includes processing elements incorporated in memory cells, sense amplifiers, and/or the logic layers of 3D memory structure 400. For example, the PIM logic 450 may be designed for specific applications, including AI applications, such as deep neural network (DNN) applications, or other like AI functions.

As shown in FIG. 4A, the 3D memory structure 400 includes a memory cell array 410 (e.g., dynamic random-access memory (DRAM)) coupled to a wordline-bitline fanout structure 420, according to various aspects of the present disclosure. In this implementation, the wordline-bitline fanout structure 420 is configured utilizing a branching pattern of pattern of wordlines and bitlines coupled to the memory cell array 410. Additionally, the wordline-bitline fanout structure 420 is coupled to nano-through silicon vias (nano-TSVs) 430, as further illustrated in FIG. 4B. In various aspects of the present disclosure, the memory cell array 410 is implemented in a layer that is vertically separated from a layer including a peripheral logic (PERI) 440 (e.g., decoder, sense-amplifiers, input/output (IO), and/or physical layer (PHY) functionality) and PIM logic 450 functions. Vertically separating the peripheral logic PERI 440 and PIM logic 450 from the memory cell array 410 enables a reduced die size, while maintaining a same bit count of the 3D memory structure 400.

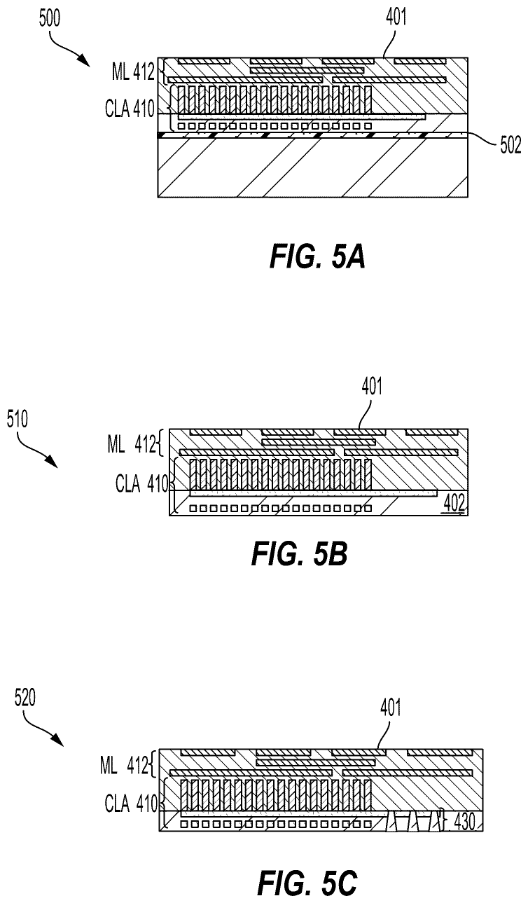

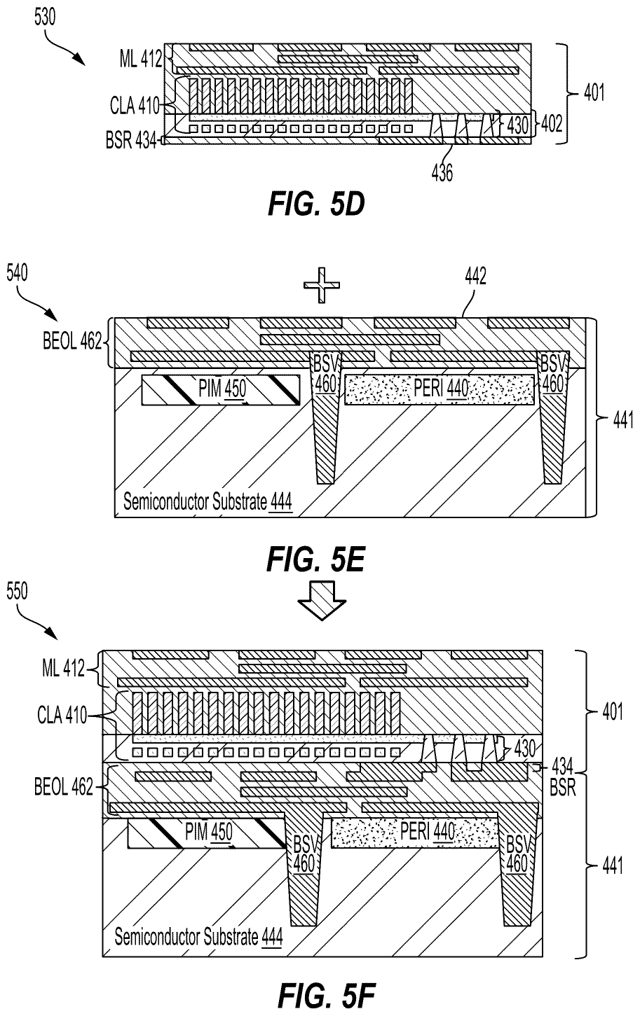

As further illustrated in FIG. 4B, the wordline-bitline fanout structure 420 includes wordlines (WL) 422 orthogonal to bitlines (BL) 426. In this example, the WL 422 are coupled to a wordline fanout (WLFO) 424, and the BL 426 are coupled to a bitline fanout (BLFO) 428. Additionally, the WLFO 424 and the BLFO 428 are coupled to respective nano-TSVs 430 through nano-TSV landing pads 432. For example, an increased pad pitch (e.g., 160 nanometers) between the nano-TSV landing pads 432 enables a nano-TSV process window, thus achieving a reduced die size, while maintaining the same bit count of the 3D memory structure 400. A process of fabricating the 3D memory structure 400 of FIG. 4A is illustrated, for example, in FIGS. 5A-5F.

FIGS. 5A-5F are cross-sectional diagrams illustrating a process for fabricating the three-dimensional (3D) memory structure 400 of FIG. 4A, having vertical separation of a memory cell array, according to various aspects of the present disclosure.

FIG. 5A illustrates a first step 500 for fabricating the 3D memory structure 400, according to various aspects of the present disclosure. At the first step 500, a first memory die 401 is formed, including a metal interconnect layer (ML) 412 and a memory cell array (CLA) 410. In this example, the first memory die 401 includes a semiconductor substrate 402 (e.g., a first semiconductor substrate) supporting the CLA 410. Additionally, the semiconductor substrate 402 includes an embedded etch stop layer 502 (e.g., silicon oxide (SiOx), silicon germanium (SiGe), etc.).

FIG. 5B illustrates a second step 510 for fabricating the 3D memory structure 400, according to various aspects of the present disclosure. The second step 510 illustrates backside thinning of the semiconductor substrate 402 that stops on the embedded etch stop layer 502 (see FIG. 5A).

FIG. 5C illustrates a third step 520 for fabricating the 3D memory structure 400, according to various aspects of the present disclosure. The third step 520 illustrates formation of the nano-TSVs 430 from a backside of the first memory die 401.

FIG. 5D illustrates a fourth step 530 for fabricating the 3D memory structure 400, according to various aspects of the present disclosure. As shown in the fourth step 530, following formation of the nano-TSVs 430, a redistribution layer (RDL) and a backside routing (BSR) layer 434 are formed on the backside of the semiconductor substrate 402 of the first memory die 401. Additionally, a hybrid bonding pad layer 436 is formed on the BSR layer 434.

FIG. 5E illustrates a fifth step 540 for fabricating the 3D memory structure 400, according to various aspects of the present disclosure. The fifth step 540 illustrates formation of a second memory die 441 having a back-end-of-line (BEOL) interconnect layer 462, contacted to an active layer of a semiconductor substrate 444 (e.g., a second semiconductor substrate). Additionally, a frontside hybrid bonding pad layer 442 is formed on the BEOL interconnect layer 462. According to various aspects of the present disclosure, the peripheral logic PERI 440 and the PIM logic 450 are formed from the active layer of the semiconductor substrate 444. Additionally, backside (BS) vias (BSV) 460 extend from the BEOL interconnect layer 462 and into the semiconductor substrate 444 to enable access to the peripheral logic PERI 440 and/or the PIM logic 450.

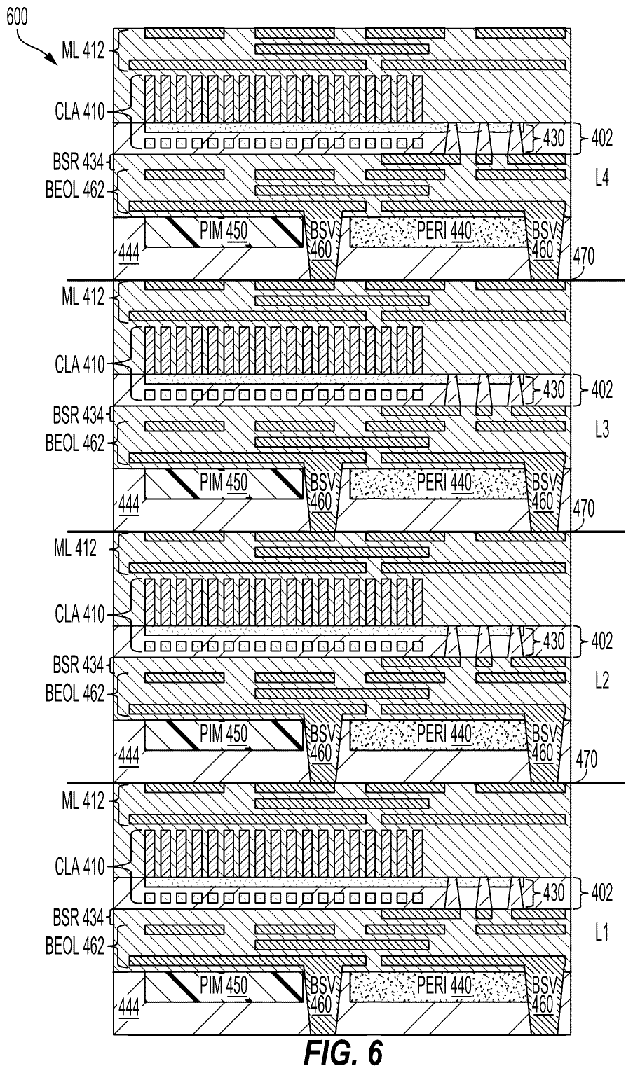

FIG. 5F illustrates a sixth step 550 for fabricating the 3D memory structure 400, according to various aspects of the present disclosure. The sixth step 550 illustrates a final hybrid bonding of the first memory die 401 and the second memory die 441 to complete formation of the 3D memory structure 400. Integration of the 3D memory structure 400 in a multilevel memory structure is illustrated, for example, in FIG. 6.

FIG. 6 illustrates a high-bandwidth memory (HBM)-processor-in-memory (PIM) structure 600 having a four-memory die height (4H) including four levels (L1, L2, L3, and L4), according to various aspects of the present disclosure. As shown in FIG. 6, the HBM-PIM structure 600 is composed of a backside hybrid bonded, four-layer stack of the 3D memory structure 400 of FIG. 4A using a hybrid bonding process (HBP). Formation of the HBM-PIM structure 600 involves a backside TSV reveal process through the semiconductor substrate 444 of each of the 3D memory structure 400 of FIG. 4. The backside TSV reveal is performed to expose each of the BSV 460 through the backside of the semiconductor substrate 444 of each of the 3D memory structure 400 of FIG. 4. The backside TSV reveal is followed by formation of a hybrid bonding pad layer 470 on a frontside of each of the bottom three of the 3D memory structure 400 of FIG. 4, which are stacked to form the HBM-PIM structure 600. In this example, the HBM-PIM structure 600 is formed without a base die, which provides significant area and power savings (e.g., 30%).

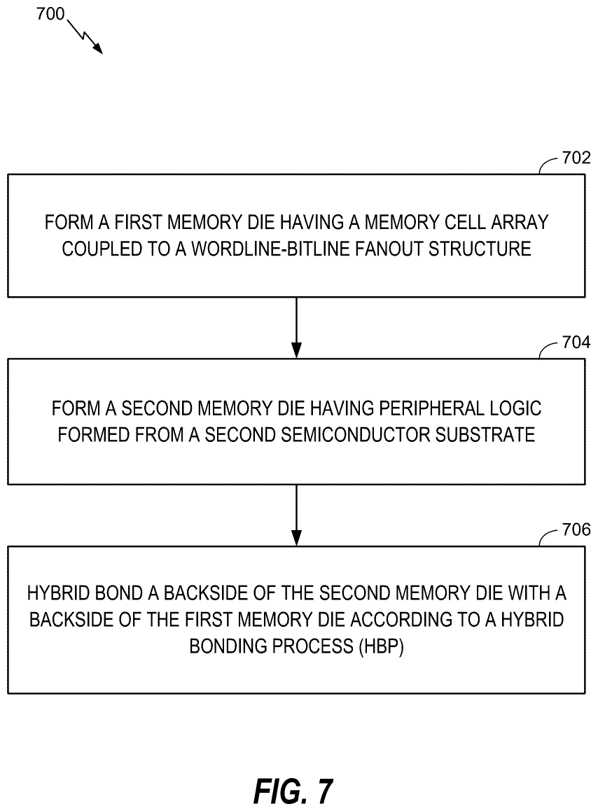

FIG. 7 is a process flow diagram illustrating a method 700 for fabricating a three-dimensional (3D) memory structure having vertical separation of a memory cell array, according to various aspects of the present disclosure. The method 700 begins a block 702, in which a first memory die is formed, having a memory cell array coupled to a wordline-bitline fanout structure. For example, as shown in FIG. 5A, at the first step 500, the first memory die 401 is formed, including a metal interconnect layer (ML) 412 and a memory cell array (CLA) 410. In this example, the first memory die 401 includes a semiconductor substrate 402 (e.g., a first semiconductor substrate) supporting the CLA. Additionally, the semiconductor substrate 402 includes an embedded etch stop layer 502 (e.g., silicon oxide (SiOx), silicon germanium (SiGe), etc.).

At block 704, a second memory die is formed, having peripheral logic formed from a second semiconductor substrate. For example, as shown in FIG. 5E, the fifth step 540 illustrates formation of a second memory die 441 having a back-end-of-line (BEOL) interconnect layer 462, contacted to an active layer of a semiconductor substrate 444 (e.g., a second semiconductor substrate). According to various aspects of the present disclosure, the peripheral logic PERI 440 and the PIM logic 450 are formed from the active layer of the semiconductor substrate 404. Additionally, backside (BS) vias (BSV) 440 extend from the BEOL interconnect layer 462 and into the semiconductor substrate 444 to enable access to the peripheral logic PERI 440 and/or the PIM logic 450.

At block 706, a backside of the second memory die is hybrid bonded with a backside of the first memory die according to a hybrid bonding process (HBP). For example, FIG. 5F illustrates a sixth step 550 for fabricating the 3D memory structure 400, according to various aspects of the present disclosure. The sixth step 550 illustrates a final hybrid bonding of the first memory die 401 and the second memory die 441 to complete formation of the 3D memory structure 400.

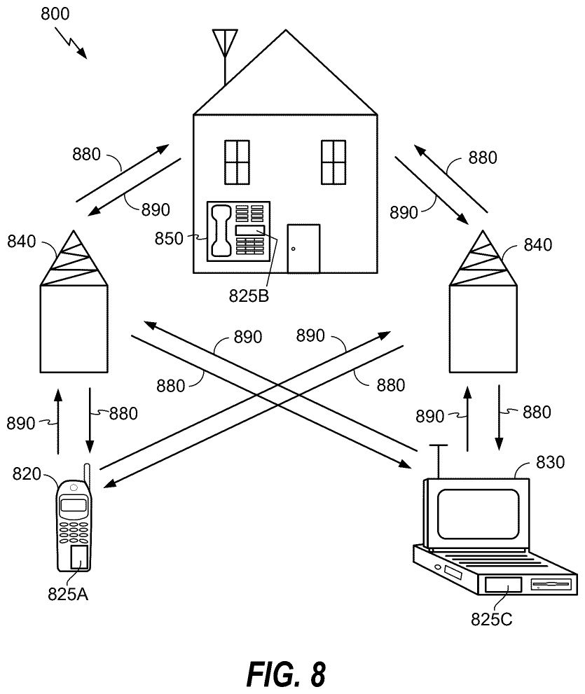

FIG. 8 is a block diagram showing an exemplary system 800, in which an aspect of the present disclosure may be advantageously employed. For purposes of illustration, FIG. 8 shows three remote units 820, 830, and 850, and two base stations 840. It will be recognized that wireless communications systems may have many more remote units and base stations. Remote units 820, 830, and 850 include integrated circuit (IC) devices 825A, 825B, and 825C that include the disclosed 3D memory structure. It will be recognized that other devices may also include the disclosed 3D memory structure, such as the base stations, switching devices, and network equipment. FIG. 8 shows forward link signals 880 from the base stations 840 to the remote units 820, 830, and 850, and reverse link signals 890 from the remote units 820, 830, and 850 to the base stations 840.

In FIG. 8, remote unit 820 is shown as a mobile telephone, remote unit 830 is shown as a portable computer, and remote unit 850 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 8 illustrates remote units according to the aspects of the present disclosure, the disclosure is not limited to these exemplary illustrated units. Aspects of the present disclosure may be suitably employed in many devices, which include the disclosed three-dimensional (3D) memory structure.

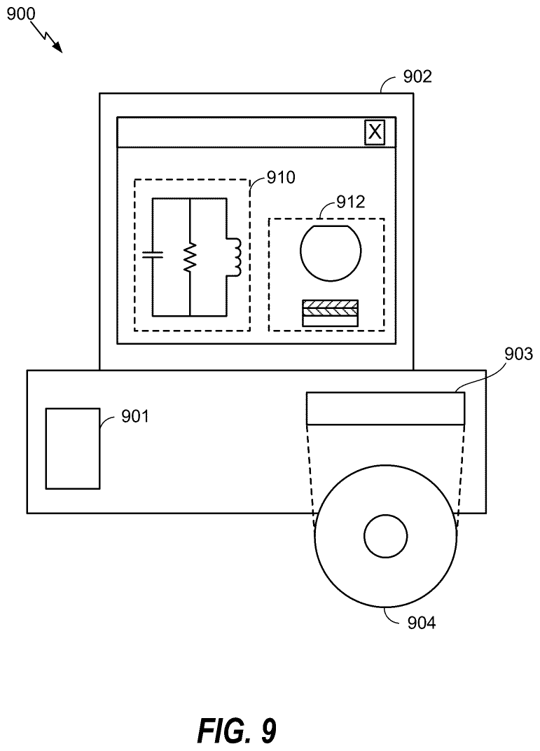

FIG. 9 is a block diagram illustrating a design workstation 900 used for circuit, layout, and logic design of a semiconductor component, such as the three-dimensional (3D) stacked chip disclosed above. The design workstation 900 includes a hard disk 901 containing operating system software, support files, and design software such as Cadence or OrCAD. The design workstation 900 also includes a display 902 to facilitate design of a circuit 910 or a semiconductor component 912, such as the 3D stacked chip. A storage medium 904 is provided for tangibly storing the design of the circuit 910 or the semiconductor component 912 (e.g., the 3D memory structure). The design of the circuit 910 or the semiconductor component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the semiconductor component 912 by decreasing the number of processes for designing semiconductor wafers.

Implementation examples are described in the following numbered clauses:
1. A three-dimensional (3D) memory structure, comprising:
a first memory die having a memory cell array coupled to a wordline-bitline fanout structure; and
a second memory die having peripheral logic formed from a second semiconductor substrate, in which a backside of the second memory die is hybrid bonded with a backside of the first memory die.
2. The 3D memory structure of clause 1, in which the memory cell array is on a first semiconductor substrate of the first memory die coupled to the peripheral logic through the wordline-bitline fanout structure.
3. The 3D memory structure of clause 2, further comprising nano-through silicon vias (nano-TSVs) from a backside of the first semiconductor substrate and coupled to the memory cell array.
4. The 3D memory structure of clause 3, in which the nano-TSVs are contacted to landing pads of the wordline-bitline fanout structure.
5. The 3D memory structure of clause 3, further comprising a metal interconnect layer (ML) on a backside of the first semiconductor substrate and coupled to the nano-TSVs.
6. The 3D memory structure of any of clauses 1-5, further comprises:
a back-end-of-line (BEOL) interconnect layer on the second semiconductor substrate; and
a backside via extending from the BEOL interconnect layer and into the second semiconductor substrate.
7. The 3D memory structure of any of clauses 1-6, in which the second memory die comprises a processor-in-memory (PIM) formed from the second semiconductor substrate.
8. The 3D memory structure of any of clauses 1-7, in which the 3D memory structure comprises a 3D dynamic random-access memory (DRAM) structure.
9. The 3D memory structure of any of clauses 1-8, in which the first memory die further comprises nano-TSVs extending from a backside of the first memory die and contacted to the memory cell array through nano-TSV landing pads of the wordline-bitline fanout structure.
10. A high-bandwidth memory (HBM)-processor-in-memory (PIM) structure, comprising a multilayer stack of three-dimensional (3D) memory structures, each of the 3D memory structures comprising:
a first memory die having a memory cell array coupled to a wordline-bitline fanout structure; and
a second memory die having peripheral logic formed from a second semiconductor substrate, in which a backside of the second memory die is hybrid bonded with a backside of the first memory die.
11. The HBM-PIM structure of clause 10, further comprising a hybrid bonding pad layer to couple the 3D memory structures in the multilayer stack of three-dimensional (3D) memory structures.
12. The HBM-PIM structure of any of clauses 10 or 11, in which the memory cell array is on a first semiconductor substrate of the first memory die coupled to the peripheral logic through the wordline-bitline fanout structure.
13. The HBM-PIM structure of clause 12, further comprising nano-through silicon vias (nano-TSVs) from a backside of the first semiconductor substrate and coupled to the memory cell array.
14. The HBM-PIM structure of clause 13, in which the nano-TSVs are contacted to landing pads of the wordline-bitline fanout structure.
15. The HBM-PIM structure of clause 13, further comprising a metal interconnect layer (ML) on a backside of the first semiconductor substrate and coupled to the nano-TSVs.
16. The HBM-PIM structure of any of clauses 10-15, further comprises:
a back-end-of-line (BEOL) interconnect layer on the second semiconductor substrate; and
a backside via extending from the BEOL interconnect layer and into the second semiconductor substrate.
17. The HBM-PIM structure of any of clauses 10-16, in which the second memory die comprises PIM logic formed from the second semiconductor substrate.
18. The HBM-PIM structure of any of clauses 10-17, in which each of the 3D memory structures comprises a 3D dynamic random-access memory (DRAM) structure.
19. The HBM-PIM structure of any of clauses 10-18, in which the first memory die further comprises nano-TSVs extending from a backside of the first memory die and contacted to the memory cell array through nano-TSV landing pads of the wordline-bitline fanout structure.
20. The HBM-PIM structure of any of clauses 10-19, in which the multilayer stack of three-dimensional 3D memory structures comprises a four-layer stack of the 3D memory structures.
21. A method for fabricating a three-dimensional (3D) memory structure, the method comprising:
forming a first memory die having a memory cell array coupled to a wordline-bitline fanout structure;
forming a second memory die having peripheral logic formed from a second semiconductor substrate; and
hybrid bonding a backside of the second memory die with a backside of the first memory die according to a hybrid bonding process (HBP).
22. The method of claim 21, in which forming the first memory die comprises:
forming the memory cell array on a first semiconductor substrate of the first memory die; and
forming an embedded etch stop layer in the first semiconductor substrate of the first memory die.
23. The method of clause 22, further comprising thinning a backside of the first semiconductor substrate of the first memory die until the embedded etch stop layer is detected.
24. The method of clause 23, further comprising forming nano-through silicon vias (nano-TSVs) from a backside of the first memory die and coupled to the memory cell array.
25. The method of clause 24, further comprising forming a metal interconnect layer (ML) on a backside of the first semiconductor substrate and coupled to the nano-TSVs.
26. The method of any of clauses 21-25, in which forming the second memory die comprises:
forming a back-end-of-line (BEOL) interconnect layer on the second semiconductor substrate; and
forming a backside via extending from the BEOL interconnect layer and into the second semiconductor substrate.
27. The method of any of clauses 21-26, in which forming the second memory die comprises forming a processor-in-memory (PIM) from the second semiconductor substrate.
28. The method of any of clauses 21-27, further comprising forming a high-bandwidth memory (HBM)-PIM structure from a four-layer stack of the 3D memory structure.
29. The method of clause 28, in which the 3D memory structure comprises a 3D dynamic random-access memory (DRAM) structure.
30. The method of any of clauses 21-29, in which forming the first memory die comprises forming nano-TSVs from a backside of the first memory die and contacted to the memory cell array through nano-TSV landing pads of the wordline-bitline fanout structure.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random-access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A three-dimensional (3D) memory structure, comprising:
a first memory die having a memory cell array coupled to a wordline-bitline fanout structure; and
a second memory die having peripheral logic formed from a second semiconductor substrate, in which a backside of the second memory die is hybrid bonded with a backside of the first memory die.

2. The 3D memory structure of claim 1, in which the memory cell array is on a first semiconductor substrate of the first memory die coupled to the peripheral logic through the wordline-bitline fanout structure.

3. The 3D memory structure of claim 2, further comprising nano-through silicon vias (nano-TSVs) from a backside of the first semiconductor substrate and coupled to the memory cell array.

4. The 3D memory structure of claim 3, in which the nano-TSVs are contacted to landing pads of the wordline-bitline fanout structure.

5. The 3D memory structure of claim 3, further comprising a metal interconnect layer (ML) on a backside of the first semiconductor substrate and coupled to the nano-TSVs.

6. The 3D memory structure of claim 1, further comprises:
a back-end-of-line (BEOL) interconnect layer on the second semiconductor substrate; and
a backside via extending from the BEOL interconnect layer and into the second semiconductor substrate.

7. The 3D memory structure of claim 1, in which the second memory die comprises a processor-in-memory (PIM) formed from the second semiconductor substrate.

8. The 3D memory structure of claim 1, in which the 3D memory structure comprises a 3D dynamic random-access memory (DRAM) structure.

9. The 3D memory structure of claim 1, in which the first memory die further comprises nano-TSVs extending from a backside of the first memory die and contacted to the memory cell array through nano-TSV landing pads of the wordline-bitline fanout structure.

10. A high-bandwidth memory (HBM)-processor-in-memory (PIM) structure, comprising a multilayer stack of three-dimensional (3D) memory structures, each of the 3D memory structures comprising:
a first memory die having a memory cell array coupled to a wordline-bitline fanout structure; and
a second memory die having peripheral logic formed from a second semiconductor substrate, in which a backside of the second memory die is hybrid bonded with a backside of the first memory die.

11. The HBM-PIM structure of claim 10, further comprising a hybrid bonding pad layer to couple the 3D memory structures in the multilayer stack of three-dimensional (3D) memory structures.

12. The HBM-PIM structure of claim 10, in which the memory cell array is on a first semiconductor substrate of the first memory die coupled to the peripheral logic through the wordline-bitline fanout structure.

13. The HBM-PIM structure of claim 12, further comprising nano-through silicon vias (nano-TSVs) from a backside of the first semiconductor substrate and coupled to the memory cell array.

14. The HBM-PIM structure of claim 13, in which the nano-TSVs are contacted to landing pads of the wordline-bitline fanout structure.

15. The HBM-PIM structure of claim 13, further comprising a metal interconnect layer (ML) on a backside of the first semiconductor substrate and coupled to the nano-TSVs.

16. The HBM-PIM structure of claim 10, further comprises:
a back-end-of-line (BEOL) interconnect layer on the second semiconductor substrate; and
a backside via extending from the BEOL interconnect layer and into the second semiconductor substrate.

17. The HBM-PIM structure of claim 10, in which the second memory die comprises PIM logic formed from the second semiconductor substrate.

18. The HBM-PIM structure of claim 10, in which each of the 3D memory structures comprises a 3D dynamic random-access memory (DRAM) structure.

19. The HBM-PIM structure of claim 10, in which the first memory die further comprises nano-TSVs extending from a backside of the first memory die and contacted to the memory cell array through nano-TSV landing pads of the wordline-bitline fanout structure.

20. The HBM-PIM structure of claim 10, in which the multilayer stack of three-dimensional 3D memory structures comprises a four-layer stack of the 3D memory structures.

21. A method for fabricating a three-dimensional (3D) memory structure, the method comprising:
forming a first memory die having a memory cell array coupled to a wordline-bitline fanout structure;
forming a second memory die having peripheral logic formed from a second semiconductor substrate; and
hybrid bonding a backside of the second memory die with a backside of the first memory die according to a hybrid bonding process (HBP).

22. The method of claim 21, in which forming the first memory die comprises:
forming the memory cell array on a first semiconductor substrate of the first memory die; and
forming an embedded etch stop layer in the first semiconductor substrate of the first memory die.

23. The method of claim 22, further comprising thinning a backside of the first semiconductor substrate of the first memory die until the embedded etch stop layer is detected.

24. The method of claim 23, further comprising forming nano-through silicon vias (nano-TSVs) from a backside of the first memory die and coupled to the memory cell array.

25. The method of claim 24, further comprising forming a metal interconnect layer (ML) on a backside of the first semiconductor substrate and coupled to the nano-TSVs.

26. The method of claim 21, in which forming the second memory die comprises:
forming a back-end-of-line (BEOL) interconnect layer on the second semiconductor substrate; and
forming a backside via extending from the BEOL interconnect layer and into the second semiconductor substrate.

27. The method of claim 21, in which forming the second memory die comprises forming a processor-in-memory (PIM) from the second semiconductor substrate.

28. The method of claim 21, further comprising forming a high-bandwidth memory (HBM)-PIM structure from a four-layer stack of the 3D memory structure.

29. The method of claim 28, in which the 3D memory structure comprises a 3D dynamic random-access memory (DRAM) structure.

30. The method of claim 21, in which forming the first memory die comprises forming nano-TSVs from a backside of the first memory die and contacted to the memory cell array through nano-TSV landing pads of the wordline-bitline fanout structure.
